(19) United States
(12) Patent Application Publication
(10) Pub. No.: US 2016/0230274 A1
(43) Pub. Date: Aug. 11, 2016

(54) MULTILAYER COATING FOR A COMPONENT

(71) Applicant: Caterpillar Inc., Peoria, IL (US)

(72) Inventors: Colm Martin Flannery, Chillicothe, IL (US); Steven Charles Taylor, Washington, IL (US); Bao Feng, Peoria, IL (US); Lucy Victoria Berg, Quitman, GA (US); Joseph Ryan Sullivan, Bartonville, IL (US)

(73) Assignee: Caterpillar Inc., Peoria, IL (US)

(21) Appl. No.: 15/132,818

(22) Filed: Apr. 19, 2016

(51) Int. Cl. C23C 16/26; C23C 14/06; C23C 16/44; C23C 14/22; C23C 16/30; C23C 16/06

(52) U.S. Cl. CPC C23C 16/26; C23C 16/30; C23C 16/06; C23C 16/44; C23C 14/22; C23C 14/0641; C23C 14/0605

(57) ABSTRACT

A multilayer coating for a metallic surface of a component is provided. The multilayer coating includes a first coating having a metal nitride. The first coating at least partially overlaps the metallic surface. The multilayer coating also includes a second coating having a metal. The second coating at least partially overlaps the first coating. The multilayer coating further includes a third coating having a Diamond Like Carbon (DLC) material. The third coating at least partially overlaps the second coating. The first coating, the second coating, and the third coating differ from one another with respect to at least one of hardness, elasticity, corrosion resistance, and lubricity. The multilayer coating includes at least ten overlapping layers having successive layers of the first coating, the second coating, and the third coating in repeating sequence.

### TECHNICAL FIELD

The present disclosure relates to a multilayer coating for a component. More specifically, the present disclosure relates to the multilayer coating to protect a metallic surface of the component from wear and tear.

### BACKGROUND

Internal combustion engines running on diesel fuel employ pumps, valves and/or fuel injectors for injecting fuel at high pressure in to the cylinders for combustion. The fuel injector includes a plunger/check which, in idle position, rests against a seat of the injector. During operation, when the fuel may be required to be injected in to the cylinder, the plunger/check may move away from the seat, thus, opening a passage for the fuel to enter the cylinder via the seat. When the fuel injection process may need to be stopped, the plunger/check may come back to its idle position with considerable force and may rest on the seat thus closing the passage.

Typically, depending on engine parameters, the plunger/check may translate with respect to the seat a couple of hundreds of times per minute. This movement of the plunger/check may create continuous impacts on the seat when the plunger/check may contact the seat. As a result, the plunger/check and/or the seat may experience accelerated wear and tear in the form of erosion, scuffing, chipping, and so on. Additionally, a pressure and a velocity of the fuel passing across the plunger/check and the seat may also be considerably high to cause wear and tear of the plunger/check and/or the seat.

U.S. Pat. No. 8,178,213 discloses a multilayer coating for a metallic surface. The coating includes at least two anti-wear layers each consisting of a diamond-like carbon (DLC) material and an intermediate layer arranged between first and second anti-wear layers. The first anti-wear layer is closer to the metallic surface. The intermediate layer is comprised of a material composition containing the DLC material. The intermediate layer includes a first transition region extending away from the first anti-wear layer over which a content of the DLC material decreases as a function of an increasing distance from the metallic surface. The intermediate layer also includes a second transition region towards the second anti-wear layer over which the content of the DLC material increases as a function of the increasing distance from the metallic surface. The intermediate layer has at least 5% by weight of the DLC material at every point.

Generally, properties of the multilayer coating may not be sufficient to resist erosion and/or crack propagation in heavy duty engine components such as the plunger/check. Hence, there is a need for an improved multilayer coating for such components.

### SUMMARY OF THE DISCLOSURE

In an aspect of the present disclosure, a multilayer coating for a metallic surface of a component is provided. The multilayer coating includes a first coating having a metal nitride. The first coating at least partially overlaps the metallic surface. The multilayer coating also includes a second coating having a metal. The second coating at least partially overlaps the first coating. The multilayer coating further includes a third coating having a Diamond Like Carbon (DLC) material. The third coating at least partially overlaps the second coating. The first coating, the second coating, and the third coating differ from one another with respect to at least one of hardness, elasticity, corrosion resistance, and lubricity. The multilayer coating includes at least ten overlapping layers having successive layers of the first coating, the second coating, and the third coating in repeating sequence.

Other features and aspects of this disclosure will be apparent from the following description and the accompanying drawings.

### BRIEF DESCRIPTION OF THE DRAWINGS

FIG. 1 is cross sectional view of a component, according to one embodiment of the present disclosure; and

FIG. 2 is a cross sectional view of a multilayer coating, according to one embodiment of the present disclosure.

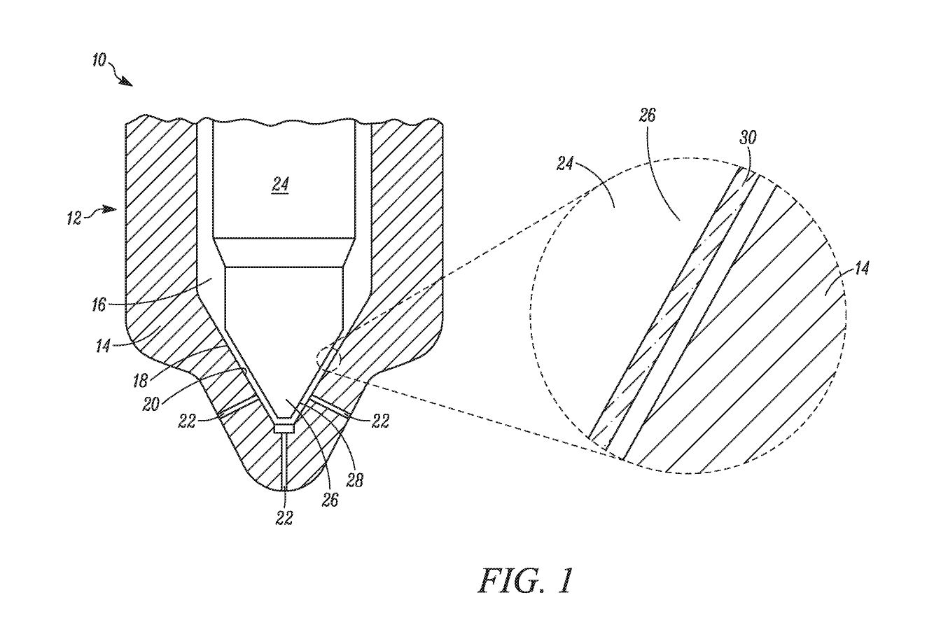

### DETAILED DESCRIPTION

Wherever possible, the same reference numbers will be used throughout the drawings to refer to the same or the like parts. Referring to FIG. 1 an exemplary component 10 is illustrated. More specifically, the component 10 is a fuel injector 12. In other embodiments, the component 10 may be any component such as a valve, a pump, a bearing, and so on.

The fuel injector 12 is configured to inject fuel wider high pressure in to one or more cylinders of an engine (not shown). The fuel injector 12 includes a body 14 having an elongate and hollow configuration defining a passage 16. The passage 16 is configured to provide a path for a flow of the fuel through the fuel injector 12. The body 14 further includes a seat 18. The seat 18 includes a conical configuration defining an inner surface 20. The body 14 includes one or more apertures 22 provided on the seat 18. The apertures 22 are configured to inject the fuel from the passage 16 into the cylinder. The body 14 and the seat 18 may be made of any metal known in the art such as steel.

The fuel injector 12 also includes a plunger 24 provided within the passage 16 of the body 14. The plunger 24 includes an elongate configuration having a conical tip 26 on one end thereof. The conical tip 26 defines an outer surface 28. During operation, the plunger 24 is configured to translate longitudinally within the passage 16. More specifically, in an idle position, the conical tip 26 of the plunger 24 may contact and rest against the seat 18. As a result, in the idle position, the plunger 24 may block the aperture 22 and prevent injection of the fuel therethrough. During an injection process, the plunger 24 may move away from the seat 18, thus, opening the aperture 22 and allowing the fuel to flow past the seat 18. The plunger 24 serves as a valving element to control the injection of the fuel through the fuel injector 12. The plunger 24 may be made of any metal known in the art such as steel.

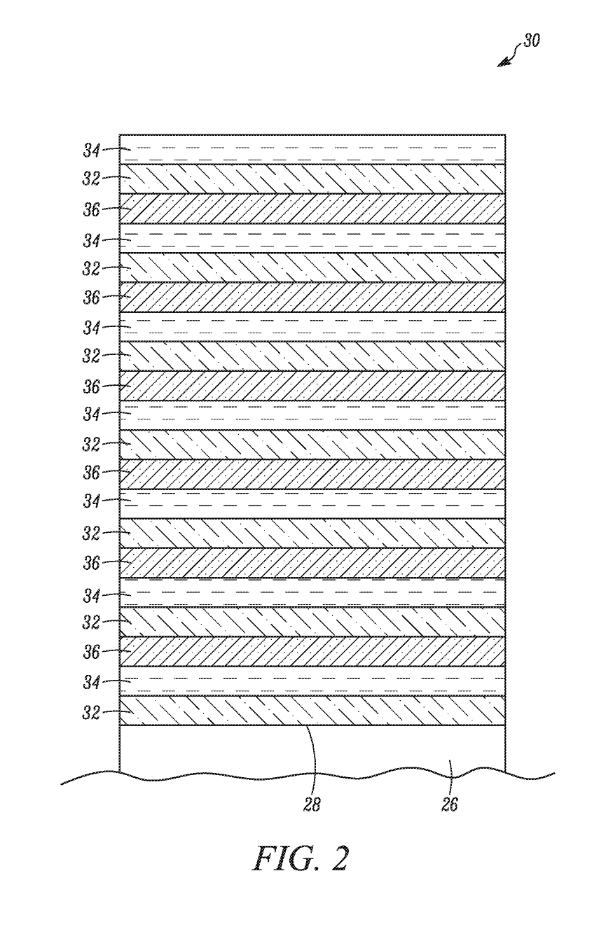

The present disclosure relates to a multilayer coating 30 provided on the outer surface 28 of the plunger 24. Alternatively, in other embodiments, the multilayer coating 30 may be provided on the inner surface 20 of the seat 18 of the fuel injector 12 based on application requirements. In yet other embodiments, the multilayer coating 30 may be provided on both the outer surface 28 of the plunger 24 and the inner surface 20 of the seat 18 of the fuel injector 12 based on application requirements. The multilayer coating 30 will be explained in more detail with reference to FIG. 2.

Referring to FIG. 2, the multilayer coating 30 includes a first coating 32. The first coating 32 may include any metal nitride known in the art such as chromium nitride. The first coating 32 is provided in a manner such that the first coating 32 at least partially overlaps a metallic surface of the plunger 24. More specifically, the first coating 32 is provided on the outer surface 28 of the conical tip 26 of the plunger 24 that contacts the inner surface 20 of the seat 18. In other embodiments, the first coating 32 may be provided on the complete outer surface 28 of the plunger 24 based on application requirements. The metal nitride provides corrosion resistance to the outer surface 28 of the plunger 24. In the illustrated embodiment, the first coating 32 includes a thickness in a range of 10-200 nanometers (nm). In other embodiments, the thickness of the first coating 32 may vary based on application requirements.

The multilayer coating 30 includes the second coating 34 provided on the first coating 32. In the illustrated embodiment, the second coating 34 is provided on the outer surface 28 of the conical tip 26 of the plunger 24 in a manner such that the second coating 34 at least partially overlaps the first coating 32. In other embodiments, the second coating 34 may be provided on the complete outer surface 28 of the plunger 24 based on application requirements. The second coating 34 may be made of any metal known in the art such as chromium.

The second coating 34 serves as an adhesion layer between the first coating 32 and a third coating 36, In the illustrated embodiment, the second coating 34 includes a thickness in orange of 10-200 nm. In other embodiments, the thickness of the second coating 34 may vary based on application requirements. Also, material properties of the second coating 34 are different from material properties of the first coating 32. More specifically, the second coating 34 differs from the first coating 32 with respect to the material properties including at least one of hardness, elasticity, corrosion resistance, and lubricity and will be explained in more detail later.

The multilayer coating 30 also includes the third coating 36 provided on the second coating 34. In the illustrated embodiment, the third coating 36 is provided on the outer surface 28 of the conical tip 26 of the plunger 24 in a manner such that the third coating 36 at least partially overlaps the second coating 34. In other embodiments, the third coating 36 may be provided on the complete outer surface 28 of the plunger 24 based on application requirements. The third coating 36 may be made of any Diamond Like Carbon (DLC) material known in the art such as tungsten DLC.

The DLC material provides lubricity to the outer surface 28 of the plunger 24. In the illustrated embodiment, the third coating 36 includes a thickness in a range of 10-200 nm. In other embodiments, the thickness of the third coating 36 may vary based on application requirements. Also, material properties of the third coating 36 are different from material properties of the first coating 32 and the second coating 34. More specifically, the third coating 36 differs from the first coating 32 and the second coating 34 with respect to the material properties including at least one of hardness, elasticity, corrosion resistance, and lubricity and will be explained in more detail later.

The multilayer coating 30 includes multiple layers of the first coating 32, the second coating 34, and the third coating 36 in order to achieve desired material properties. More specifically, the multilayer coating 30 includes successive layers of the first coating 32, the second coating 34, and the third coating 36 in repeating sequence.

In some embodiments, the sequence of layering of the first coating 32, the second coating 34, and the third coating 36 may be varied to vary the material properties of the multilayer coating 30. For example, in some embodiments, the first coating 32 may be followed by the third coating 36. The third coating 36 may be again followed by the second coating 34. The second coating 34 may then be followed by the first coating 32, and so on In some embodiments, any of the first coating 32, the second coating 34, and the third coating 36 may be omitted between a couple of alternating layers before being reintroduced again. Repeating layers of the first coating 32, the second coating 34, and the third coating 36 may be applied in any sequence and in a manner such that a total number of layers in the multilayer coating 30 may be at least ten.

It should be noted that the sequence of application of the first coating 32, the second coating 34, and the third coating 36 disclosed herein is merely exemplary. In other embodiments, the sequence of application of the first coating 32, the second coating 34, and the third coating 36 may be interchanged to vary the material properties of the multilayer coating 30 based on application requirements. Also, in some embodiments, the second coating 34 of the metal disclosed herein may be optional. As such, in such situations, the multilayer coating 30 may include repeated layers of the first coating 32 and the third coating 36 with the second coating 34 omitted.

A thickness of each of the first coating 32, the second coating 34, and the third coating 36 may also be varied throughout the ten layers of the multilayer coating 30 in order to vary the material properties of the multilayer coating 30. Further, the multilayer coating 30 may be provided on the outer surface 28 of the plunger 24 by any known deposition process known in the art such as Chemical Vapor Deposition (CVD), Physical Vapor Deposition (PVD), and so on.

### INDUSTRIAL APPLICABILITY

The present disclosure relates to the multilayer coating 30 for metallic surfaces. The multilayer coating 30 includes the alternating layers of the first coating 32, the second coating 34, and the third coating 36. The alternating layers provide a combination of different material properties in a single coating. The thickness of each of the first coating 32, the second coating 34, and the third coating 36 may be varied or maintained constant throughout the multilayer coating 30 to optimize the multilayer coating 30 for material properties such as impact wear, debris wear, rolling wear, sliding wear, scuffing wear, conosion resistance, and so on.

The multilayer coating 30 may be used for any component which may impact another component thus resulting in cyclic loading and impact wear such as a check valve, a valve seat of an engine, the seat 18 of the fuel injector 12, and so on. Also, the multilayer coating 30 may be used for sliding applications such as the plunger 24 of the fuel injector 12, the pump, a bearing, and so on where protection against rolling wear, scuffing wear, sliding wear, and lubricity may be required. In some embodiments, the multilayer coating 30 may be used for applications requiring protection against a combination of impact wear, rolling wear, scuffing wear, sliding wear, and lubricity. It should be noted that the multilayer coating 30 may be used for any component having applications other than the engine such as a drivetrain without limiting the scope of the disclosure.

In some embodiments, the metal nitride used in the respective first coatings 32 of the multilayer coating 30 may include different metals for differing the material properties of the respective first coatings 32 of the multilayer coating 30, In some embodiments, a concentration of the metal of the metal nitride used in the respective first coatings 32 of the multilayer coating 30 may be varied for differing the material properties of the respective first coatings 32 of the multilayer coating 30.

The multilayer coating 30 provides alternating layers of the first coating 32, the second coating 34, and the third coating 36 to reduce generation of corrosion pathways. The multilayer coating 30 provides difference of material properties such as elasticity between the alternating layers of the first coating 32, the second coating 34, and the third coating 36. This results in an impedance mismatch which in turn reduces crack propagation through dissipation of crack energy, reflection of energy, blunting of crack tip, nanoscale plastic deformation, and so on.

The multilayer coating 30 provides controlled wear due to controlled sacrifice of the alternating layers of the first coating 32, the second coating 34, and the third coating 36. More specifically, the wear is limited to the thickness of individual layers of the alternating layers and may prevent removal of the complete multilayer coating 30.

The multilayer coating 30 provides tuning of the hardness due to the alternating layers. By altering the thicknesses of each of the alternating layers, the hardness of each of the alternating layers may be tuned and increased while maintaining an elastic modulus of each of the alternating layers as constant. More specifically, a Hardness to Elastic Modulus (H/E) ratio of the multilayer coating 30 may be tuned by varying the thickness of each of the first coating 32, the second coating 34, and the third coating 36 of the alternating layers. A higher H/E ratio may provide better wear performance. Further, low thickness of the alternating layers of the multilayer coating 30 may increase the hardness due to pinning of dislocations at interfaces and reducing plastic deformation. An overall effect of the alternating layers of the first coating 32, the second coating 34, and the third coating 36 may provide accurate tuning and/or increasing of the H/E ratio which may not be achieved by mixing of different material properties.

The multilayer coating 30 includes the alternating layers of the first coating 32, the second coating 34, and the third coating 36 in order to control and limit grain size and columnar growth. More specifically, low thickness of the alternating layers of the multilayer coating 30 allows for stress relief, growth of coatings with more repeatability, less sensitivity to fabrication parameters, and allow fabrication of thicker alternating layers when needed with improved adhesion between the alternating layers. The multilayer coating 30 also provides improved lubricity and improved corrosion resistance in the same multilayer coating 30. The first coating 32 provides corrosion resistance and the third coating 36 provides lubricity in the same multilayer coating 30. The multilayer coating 30 thus provides improved wear properties, improved lubricity, and improved anti-corrosion properties for both impact wear and sliding/scuffing wear.

While aspects of the present disclosure have been particularly shown and described with reference to the embodiments above, it will be understood by those skilled in the art that various additional embodiments may be contemplated by the modification of the disclosed machines, systems and methods without departing from the spirit and scope of the disclosure. Such embodiments should be understood to fall within the scope of the present disclosure as determined based upon the claims and any equivalents thereof.

What is claimed is:

1. A multilayer coating for a metallic surface of a component, the multilayer coating comprising:
a first coating including a metal nitride, wherein the first coating at least partially overlaps the metallic surface;
a second coating including a metal, wherein the second coating at least partially overlaps the first coating; and
a third coating including a Diamond Like Carbon (DLC) material, wherein the third coating at least partially overlaps the second coating, wherein the first coating, the second coating, and the third coating differ from one another with respect to at least one of hardness, elasticity, corrosion resistance, and lubricity, and
wherein the multilayer coating includes at least ten overlapping layers having successive layers of the first coating, the second coating, and the third coating in repeating sequence.
